(19) United States
(12) Patent Application Publication
(10) Pub. No.: US 2002/0164871 A1
(43) Pub. Date: Nov. 7, 2002

(54) Method for manufacturing a trench DRAM

(76) Inventors: Chih-Cheng Liu, Taipei (TW); Der-Yuan Wu, Hsin-Chu City (TW)

Correspondence Address: POWELL, GOLDSTEIN,, FRAZER & MURPHY LLP, P.O. BOX 97223, WASHINGTON, DC, 20090-7223, US

(21) Appl. No.: 09/847,109

(22) Filed: May 2, 2001

(51) Int. Cl. H01L 21/4763

(52) U.S. Cl. 438/637

(57) ABSTRACT

The present invention provides a method to manufacture a trench DRAM. The present method can avoid the latch-up phenomenon of a transistor, and can efficiently increase the ability of storing charge of a capacitor to avoid the soft errors caused by α particles. In this method, an SOI is used to manufacture the trench DRAM. Because a dielectric layer in SOI separates the transistor from the substrate, the latch-up phenomenon can be avoided. By using oxygen-ion implantation, silicon layers can be divided, and elements can adequately be separated from each other.

### BACKGROUND

1. Field of the Invention

The present invention generally relates to a method for manufacturing a trench DRAM, and in particular to a method for manufacturing an SOI trench DRAM.

2. Description of the Prior Art

A conventional trench dynamic random access memory (trench DRAM) consists of a transistor and a trench capacitor. Using a trench to form a capacitor can efficiently improve the surface area but not degrade the integration.

A conventional method of forming a trench DRAM comprises the following steps: first, as shown in FIG. 1A, an n-type substrate 101 is provided, then a trench 102 is formed in the substrate 101. Afterward, an arsenosilicate glass solution 103 is poured into the trench 102, as shown in FIG. 1B. Then, a heating step is performed to evaporate the solvent, so an arsenosilicate glass layer is formed on the surface of the trench 102. At the same time, the arsenic ions are diffused into the substrate 101 to form an n+ region which can be used as a lower electrode 104 of a capacitor, as shown in FIG. 1C and FIG. 1D. Afterward, a dielectric layer 105, such as oxide-nitride-oxide (ONO) layer, is conformally formed in the trench 102. A polysilicon layer 106 is deposited to fill up the trench 102, as shown in FIG. 1F. An etching step is performed to remove partial dielectric layer 105 and partial polysilicon layer 106, so another trench 108 is formed. The remaining part of the dielectric layer 105 is used as a interlayer dielectric of the capacitor, and the remaining part of the polysilicon layer 106 is used as the upper electrode 107 of the capacitor, as shown in FIG. 1G. Then, a dielectric layer 109 is deposited in the trench and on the surface of the substrate 101, as shown in FIG. 1H. A part of the dielectric layer 109 is etched, and then the remaining part of the dielectric layer 109 is used as a barrier layer 110, as shown in FIG. 1I. The barrier layer 110 is used to separate the lower electrode of the capacitor from other conductor, such as upper electrode and lines. Then, a polysilicon layer 111 is deposited in the trench and is used as a conductive line to connect to the upper electrode 107, as shown in FIG. 1J. A p-well is then formed in substrate 101, as shown in FIG. 1K. Then, a gate 112, a source 113 and a drain 114 of a MOS is respectively formed. The source 113 is formed in the p-well 115. The drain 114 is formed in the polysilicon layer 111 and is electrically connected to the upper electrode 107 of the capacitor through the polysilicon layer 111.

In the conventional method, a latch-up phenomenon may occur in the transistor because of a connection between the source and the substrate or a connection between the well and the substrate. The latch-up phenomenon can be avoided by using a silicon on insulator (SOI) to separate the transistor from the substrate.

### SUMMARY

It is an object of the invention to provide a method for manufacturing a trench DRAM.

It is another object of the invention to provide a method to prevent the latch-up phenomenon of a transistor.

It is a further object of the invention to provide a method of increasing the ability of storing charge of a capacitor to avoid the soft errors caused by α particles.

According to the foregoing objects, the present invention provides a method comprising the following steps: a structure with an SOI is provided, and the SOI comprises a first dielectric layer and a first silicon layer on the first dielectric layer. Then, an etching step is performed to remove partial the first silicon layer and partial the first dielectric layer to form a first trench. An oxygen-ion implantation is performed on the first silicon layer to form a first silicon oxide layer. The silicon oxide layer divides the first silicon layer into two part: one is a second silicon layer beneath the first silicon oxide layer, another is a third silicon layer above the first silicon oxide layer. Then, a first conductive layer, such as polysilicon layer, is formed in the trench. A part of the first conductive layer is then etched to form the lower electrode of the trench capacitor. Afterward, a second dielectric layer, such as silicon oxide layer or oxide-nitride-oxide (ONO) layer, is deposited in the first trench to cover the first conductive layer. A second conductive layer, such as polysilicon layer, is then deposited in the trench to cover the second dielectric layer. Afterward, a second trench is formed by removing partial region of the second conductive layer and the second dielectric layer. The remaining part of the second conductive layer is used as the upper electrode of the trench capacitor, and the remaining part of the second dielectric layer is used as the interlayer dielectric (ILD) of the trench capacitor. The trench capacitor is completed so far. The second silicon layer may be exposed after the above etching step, so a barrier layer is formed in order to avoid this problem. The barrier layer can be formed by the following steps: a third dielectric layer is deposited in the second trench. Then, a part of the third dielectric layer is removed to expose partial upper electrode and partial third silicon layer. The remaining part of the third dielectric layer is used as the barrier layer. Afterward, a polysilicon layer is deposited to fill up the second trench, wherein the polysilicon layer is used as a contact plug, and is electrically connected to the upper electrode of the trench capacitor. Then, a transistor is formed on the third silicon layer. The drain of the transistor is positioned on the contact plug and is electrically connected to the upper electrode of the trench capacitor. Afterward, a part of the third silicon layer, the first silicon oxide, and second seilicon layer is removed to form a third trench. A fourth dielectric layer is deposited in the third trench, and is then partially removed to expose a part of the second silicon layer. A third conductive layer, such as polysilicon or metal tungsten, is deposited to fill up the third trench, and is used as a pickup which is electrically connected to the upper electrode of the trench capacitor through the second silicon layer.

In another embodiment of the present invention, we provide a method for suppressing the formation of leakage current by applying a reverse voltage to the transistor. The formation of the present trench DRAM is similar to the above, but an extra oxygen-ion implantation is performed on the third silicon layer to form a second silicon oxide layer. The second silicon oxide layer divides the third silicon layer into a fourth silicon layer beneath the second silicon oxide layer and a fifth silicon layer above the second silicon oxide layer. It should be noted that the thickness of the barrier layer must be greater than that of the fourth silicon layer, so the fourth silicon layer can be completely separated from the contact plug. Afterward, a removal of partial fifth silicon layer, partial second silicon oxide layer, partial fourth silicon layer, partial first silicon oxide layer, and partial second silicon layer is done to form a trench. A dielectric layer is conformally deposited in the trench and a part of the dielectric layer is then removed to expose the second silicon layer. Afterward, a conductive layer is deposited to fill up the trench, and is used as a first pickup which is electrically connected to the lower electrode of the capacitor. Then, an etching step is performed to remove partial fifth silicon layer, partial second silicon oxide layer, and partial fourth silicon layer to form another trench. Another dielectric layer is then conformally deposited in the trench, and then a part of the dielectric layer is removed to expose the fourth silicon layer. Another conductive layer is deposited to fill up the trench, and is used as a second pickup by which we can apply a reverse voltage to the transistor.

### BRIEF DESCRIPTION OF THE DRAWINGS

The foregoing aspects and many of the accompanying advantages of this invention will become more readily appreciated as the same becomes better understood by reference to the following detailed description, when taken in conjunction with the accompanying drawings, wherein:

FIG. 1A to FIG. 1K show a series of schematic cross-sectional diagrams of a conventional method of manufacturing a trench DRAM;

FIG. 2A to FIG. 2N show a series of schematic cross-sectional diagrams of an embodiment according to the present method for manufacturing a trench DRAM;

FIG. 3A to FIG. 3C show a series of schematic cross-sectional diagrams of another embodiment according to the present method for manufacturing a trench DRAM.

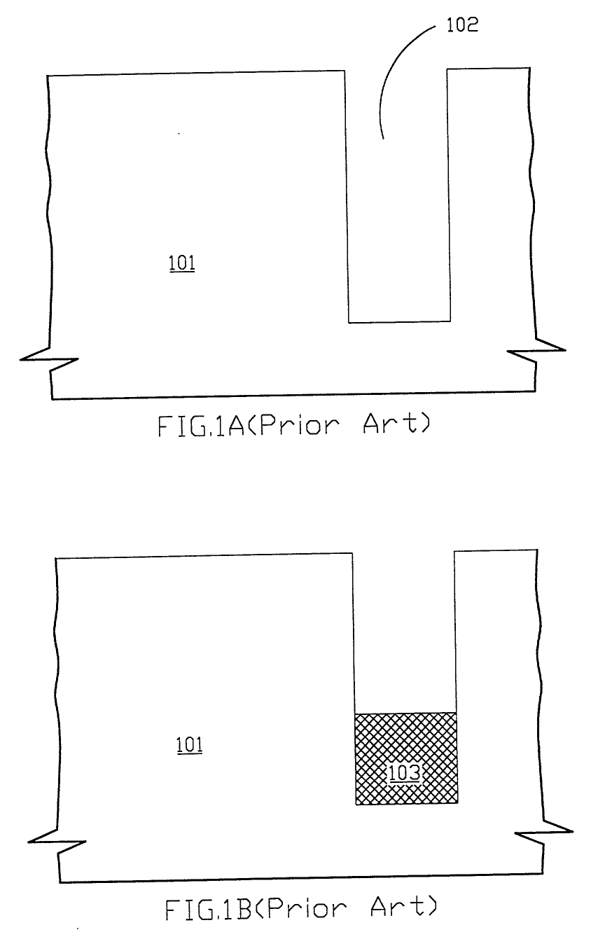

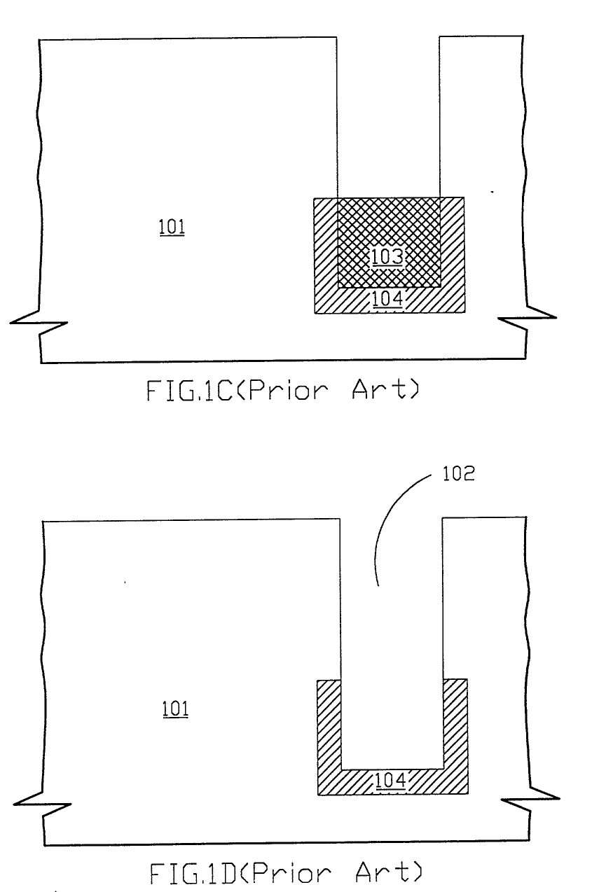

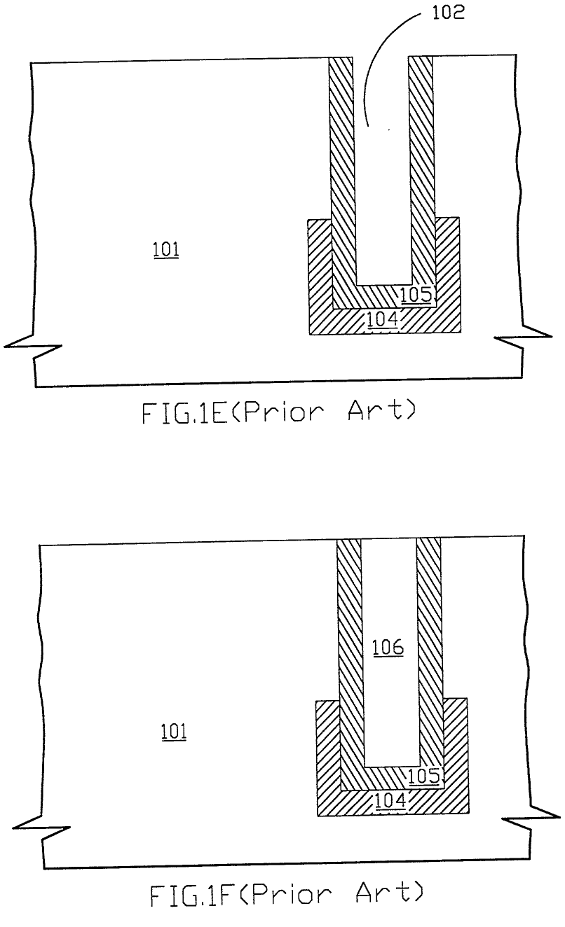

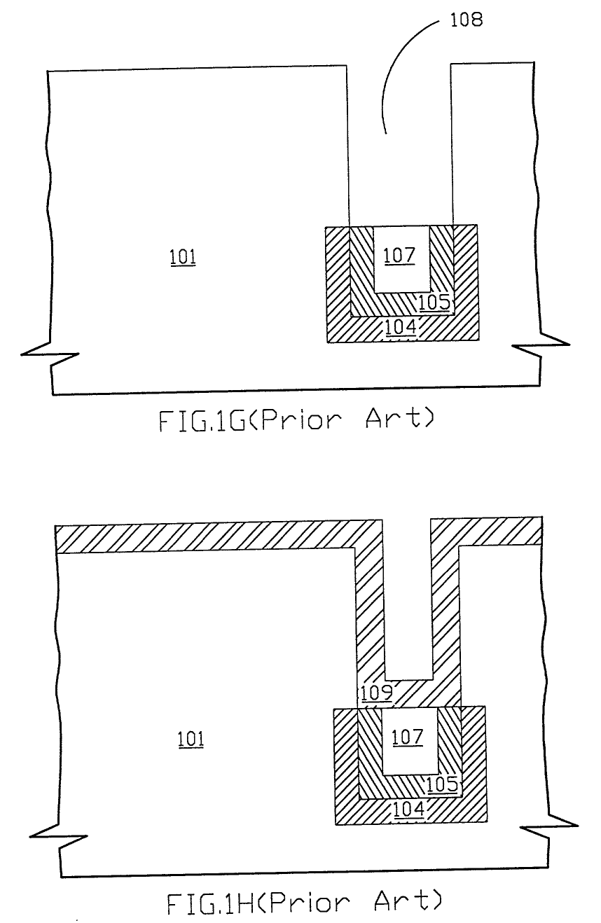

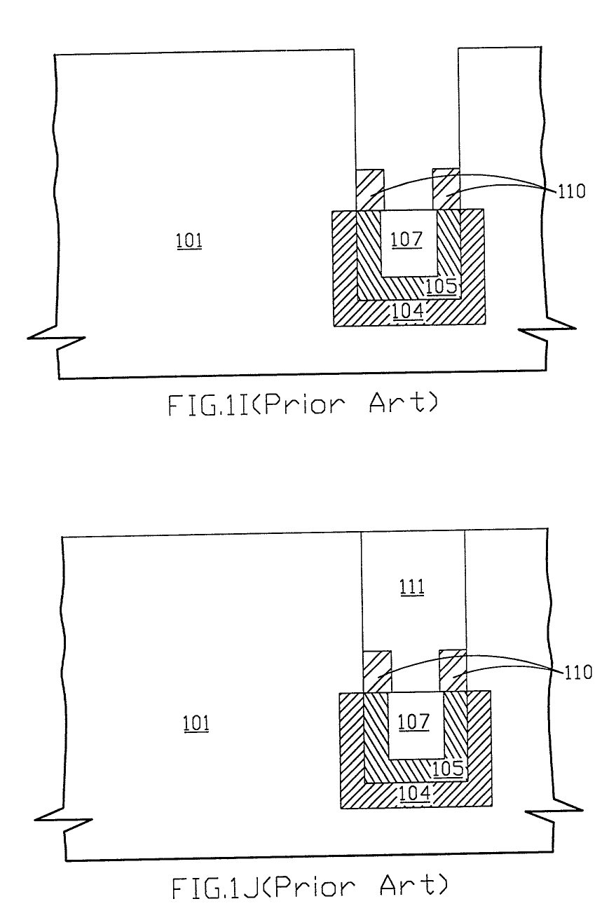

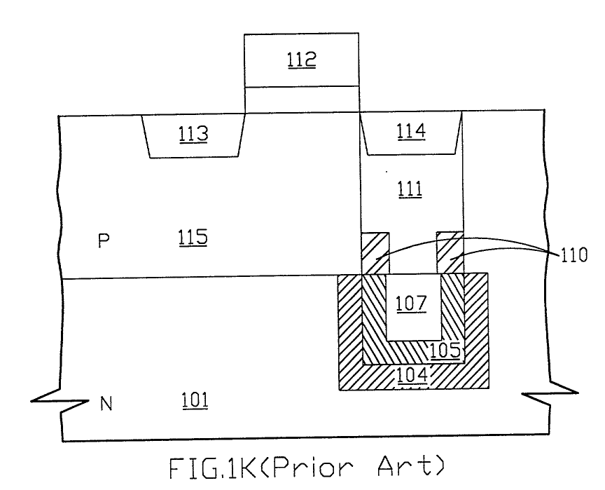

### DESCRIPTION OF THE PREFERRED EMBODIMENT

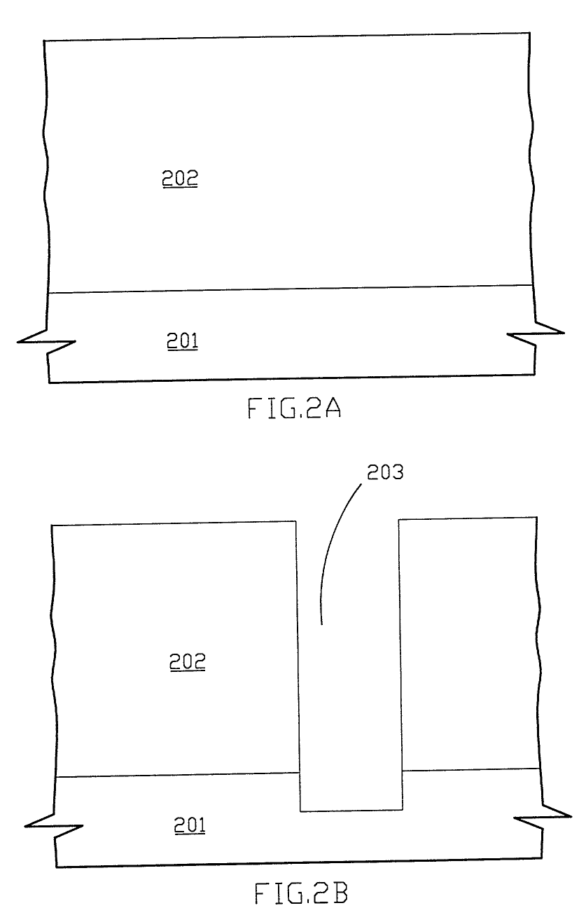

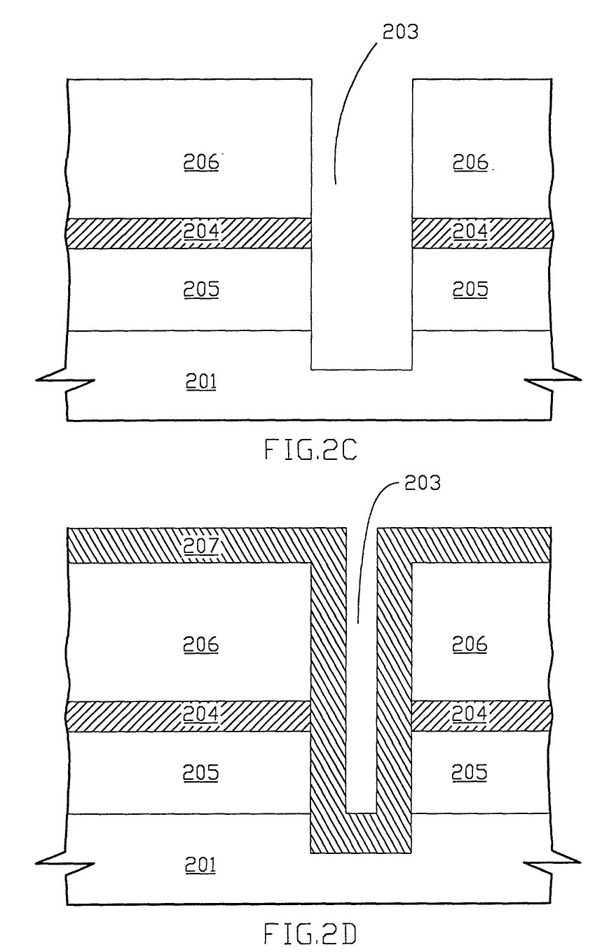

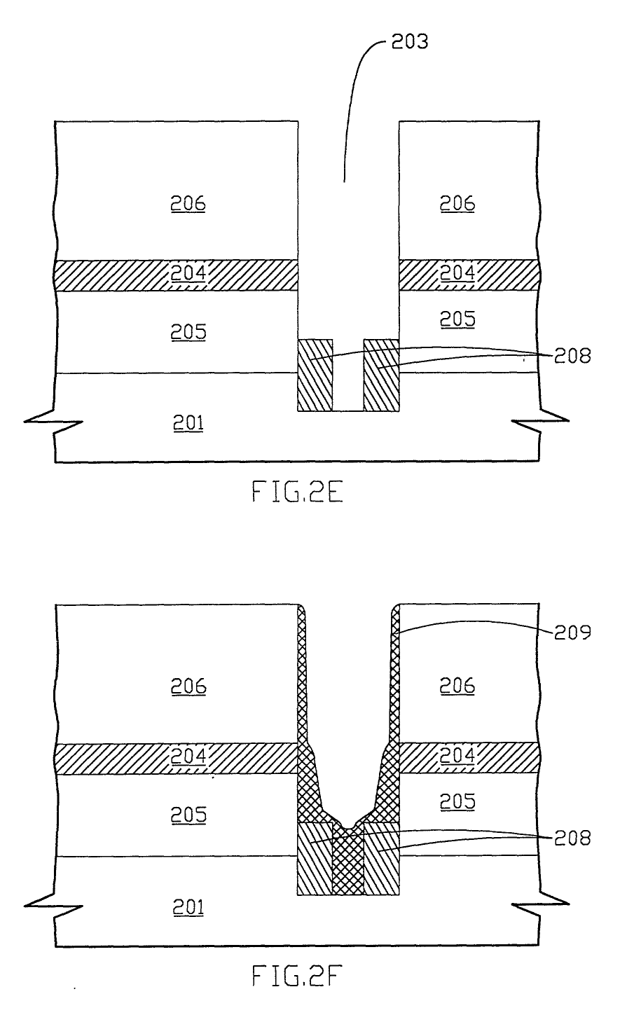

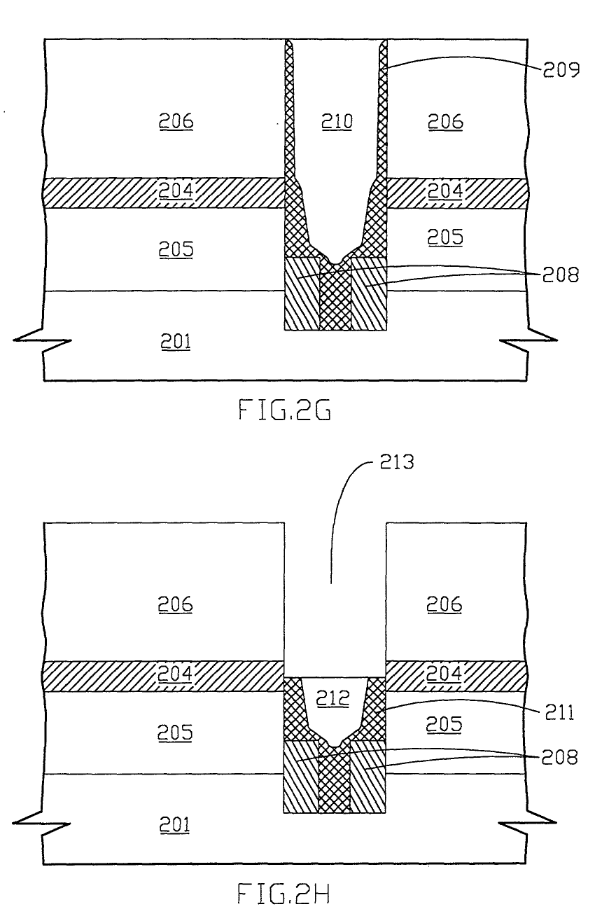

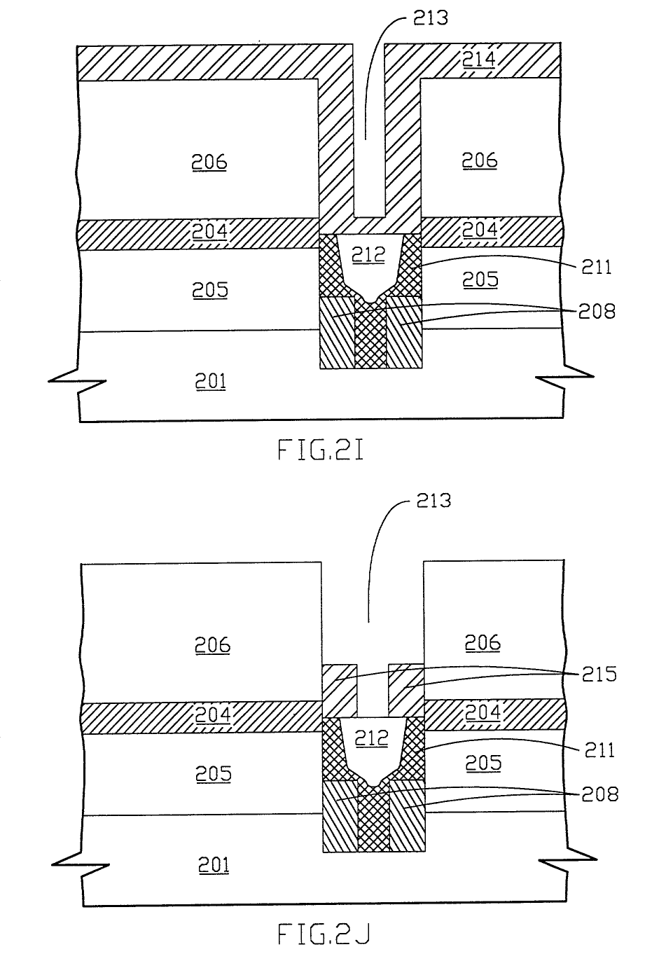

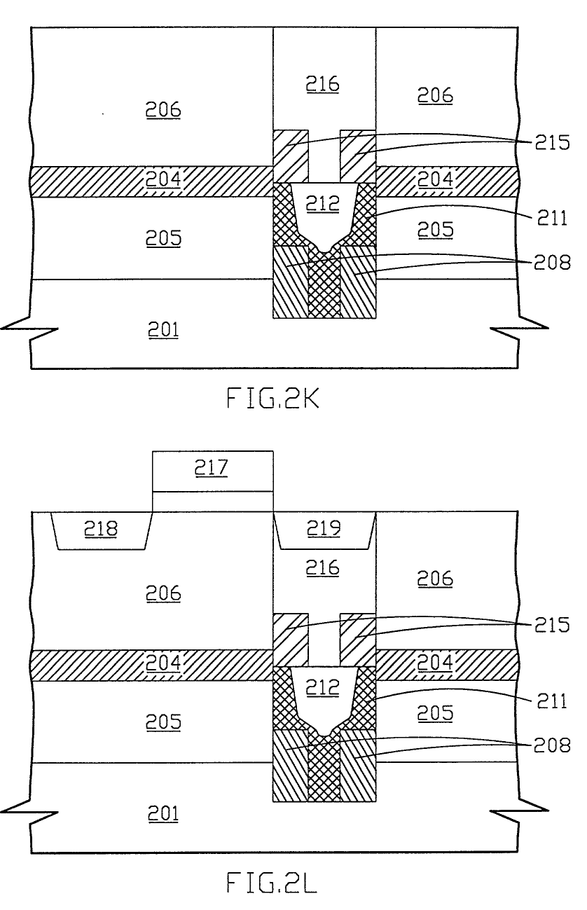

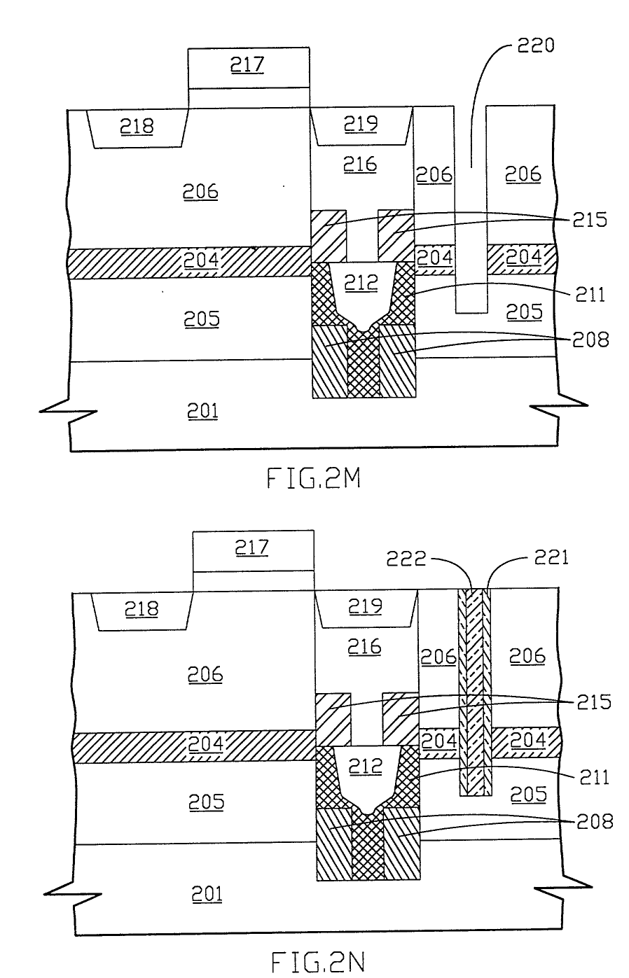

In present invention, we provide a method for manufacturing an SOI trench DRAM. The method comprises the following steps: first, an SOI which consists of a silicon oxide layer 201 and a first silicon layer 202 is provided, as shown in FIG. 2A. A part of the first silicon layer 202 and the silicon oxide layer 201 is etched to form a trench 203, as shown in FIG. 2B. Then, an oxygen-ion implantation is performed on the first silicon layer 202 to form a silicon oxide layer 204, so the first silicon layer 202 is divided into a second silicon layer 205 and a third silicon layer 206, as shown in FIG. 2C. Afterward, a polysilicon layer 207 is conformally deposited in the trench 203 to cover the surface of the second silicon layer 205, the silicon oxide layer 204, and the third silicon layer 206, as shown in FIG. 2D. An etching step is performed to remove a part of the polysilicon 207 layer above the silicon oxide layer 204, and the remaining part of the polysilicon layer 207 is used as a lower electrode 208 of a capacitor, as shown in FIG. 2E. A dielectric layer, such as oxide-nitride-oxide (ONO), is then conformally deposited in the trench 203, as shown in FIG. 2F. Afterward, a polysilicon layer 210 is deposited to fill up the trench 203, as shown in FIG. 2G. An etching step is performed to remove partial dielectric layer 209 and partial polysilicon layer 210 above the silicon oxide layer 204, so another trench 213 is formed. The remaining part of the dielectric layer 209 is used as the interlayer dielectric layer 211 in the capacitor, and the remaining part of the polysilicon layer 210 is used as the upper electrode 212 of the capacitor, as shown in FIG. 2H. To avoid the second silicon layer 205 be exposed by an etch, a silicon oxide layer 214 is conformed deposited in the trench 213, as shown in FIG. 2I. Then, a part of the silicon oxide layer 214 is etched to expose a part of the upper electrode 212. The remaining part of the silicon oxide layer 214 is used as a barrier layer 215 to avoid the second silicon layer 205 be exposed, as shown in FIG. 2J. Then, a polysilicon layer is deposited to fill up the trench 213, the polysilicon layer is used as a contact plug 216 to connect to the upper electrode 212 of the capacitor, as shown in FIG. 2K. Afterward, a gate 217, a source 218, and a drain 219 are formed on the third silicon layer 206, wherein the drain 219 is on the contact plug 216 and electrically connected to the upper electrode 212 of the capacitor through the contact plug 216, as shown in FIG. 2L. By etching away partial third silicon layer 206, partial silicon oxide layer 204, and partial second silicon layer 205 to form a trench 220, as shown in FIG. 2M. A dielectric layer 221, such as silicon oxide layer, is deposited in the trench 220, and a part of the dielectric layer 221 is then etched to expose the second silicon layer 205. Afterward, a conductive layer 222, such as polysilicon or metal tungsten, is deposited to fill up the trench 220, and is used as a pickup, as shown in FIG. 2N. The pickup is electrically connected to the lower electrode 208 of the capacitor through the second silicon layer 205.

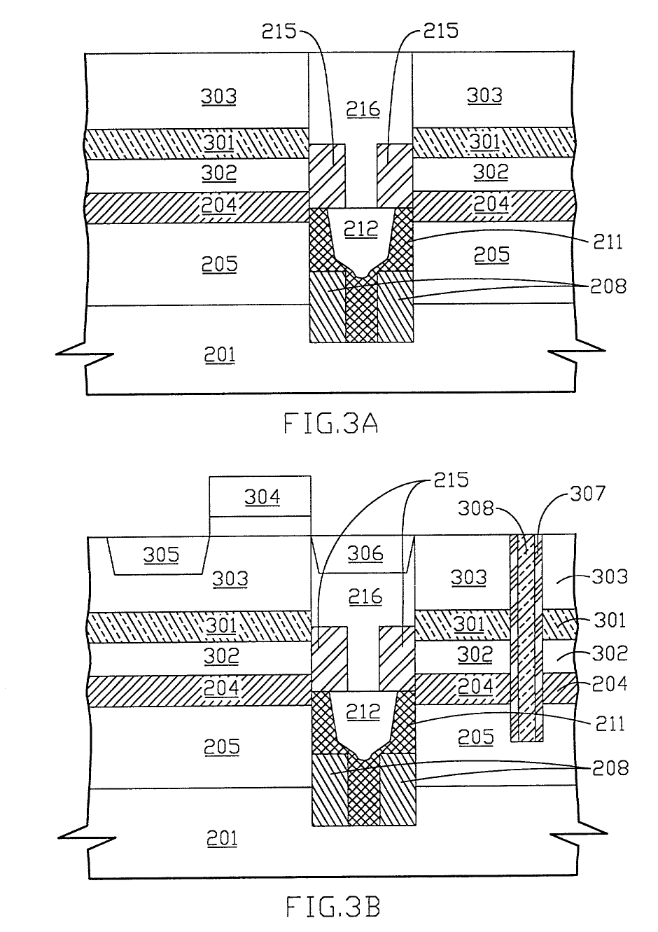

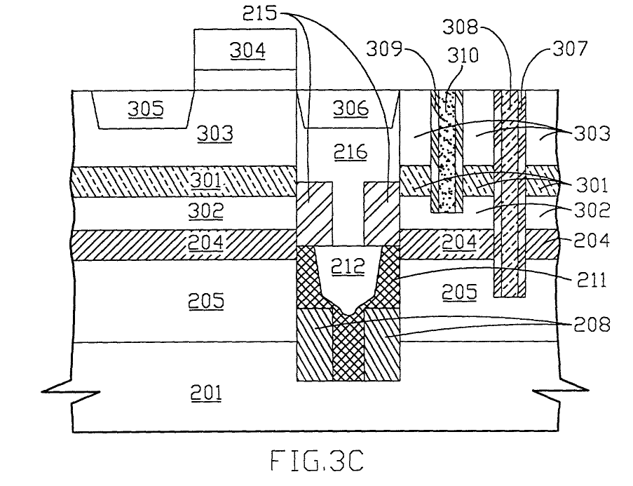

In another embodiment, as shown in FIG. 3A, the method for manufacturing a capacitor is similar to the above one, but an extra oxygen-ion implantation is performed on the third silicon layer 206 to form a silicon oxide layer 301, so that the third silicon layer 206 is divided into a fourth silicon layer 302 and a fifth silicon layer 303. The thickness of barrier layer 215 is larger than that of the fourth silicon layer 302, so that the fourth silicon layer is completely separated from the contact plug 216. As shown in FIG. 3B, an etching step is performed to remove partial fifth silicon layer 303, partial silicon oxide layer 301, partial fourth silicon layer 302, partial silicon oxide layer 204, and partial second silicon layer 205, so a new trench is formed. Afterward, a dielectric layer 307 is conformally deposited in the trench. A part of the dielectric layer 307 is then etched to expose the second silicon layer 205. A conductive layer is then deposited to fill up the trench and is used as a first pickup 308. The first pickup 308 is electrically connected to the lower electrode 208 of the capacitor through the second silicon layer 205. In order that we could apply a voltage to the transistor to suppress the occurrence of a leakage current, we can manufacture another pickup to achieve this aim. As shown in FIG. 3C, an etching step is performed to remove partial the fifth silicon layer 303, the silicon oxide layer 301, and the fourth silicon layer 202 to form another trench. A dielectric layer 309 is then conformally deposited in the trench. Afterward, a part of the dielectric layer 309 is etched to expose the fourth silicon layer 302. Then a conductive layer is deposited to fill up the trench and is used as a second pickup 310.

Although specific embodiments have been illustrated and described, it will be obvious to those skilled in the art that various modifications may be made without departing from what is intended to be limited solely by the appended claims.

What is claimed is:

1. A method for manufacturing a trench capacitor, said method comprising the steps of:
providing a structure, said structure comprises a first dielectric layer and a first silicon layer on said first dielectric layer;
removing partial said first silicon layer and partial said first dielectric layer to form a first trench;
performing an oxygen-ion implantation on said first silicon layer to form a first silicon oxide layer, wherein said first silicon oxide layer divides said first silicon layer into two parts: one is a second silicon layer beneath said first silicon oxide layer, and the other is a third silicon layer over said first silicon oxide layer;
depositing a first conductive layer in said first trench to cover the surface of said third silicon layer, said first silicon oxide layer, said second silicon layer, and said first dielectric layer;
removing partial said first conductive layer to expose said third silicon layer and a partial region of said first dielectric layer, wherein the remaining part of said first conductive layer is used as a first electrode of said trench capacitor;
depositing a second dielectric layer in said first trench to cover said partial region of said first dielectric layer and said remaining part of said first conductive layer;
depositing a second conductive layer in said first trench to cover said second dielectric layer;
removing partial said second conductive layer and partial said second dielectric layer to form a second trench, wherein the remaining part of said second conductive layer is used as a second electrode of said trench capacitor, and the remaining part of said second dielectric layer is used as a interlayer dielectric (ILD) in said trench capacitor;
depositing a third dielectric layer in said second trench to cover the surface of said second dielectric layer, said second conductive layer, and said third silicon layer;
removing partial said third dielectric layer to expose partial said second conductive layer and partial said third silicon layer;
depositing a polysilicon layer to fill up said second trench, wherein said polysilicon layer is used as a contact plug and is electronically connected to said second electrode of said trench capacitor;
removing partial said third silicon layer, partial first silicon oxide layer, and partial said second silicon layer to form a third trench;
depositing a fourth dielectric layer in said third trench to cover the surface of said third silicon layer, said first silicon oxide layer, and said second silicon layer;
removing partial said fourth dielectric layer to expose partial said second silicon layer; and
depositing a third conductive layer to fill up said third trench, wherein said third conductive layer is electrically connected to said first electrode of said trench capacitor through said second silicon layer.

2. The method according to claim 1, wherein said first dielectric layer, said second dielectric layer, said third dielectric layer, and said fourth dielectric layer are silicon oxide layers.

3. The method according to claim 1, wherein said second dielectric layer is an oxide-nitride-oxide layer.

4. The method according to claim 1, wherein said first conductive layer, said second conductive layer, and said third conductive layer are polysilicon layers.

5. A method for manufacturing a trench DRAM, said method comprising the steps of:
providing a structure, said structure comprises a first dielectric layer and a first silicon layer on said first dielectric layer;
removing partial said first silicon layer and partial said first dielectric layer to form a first trench;
performing a first oxygen-ion implantation on said first silicon layer to form a first silicon oxide layer, wherein said first silicon oxide layer divides said first silicon layer into two parts: one is a second silicon layer beneath said first silicon oxide layer, and the other is a third silicon layer over said first silicon oxide layer;
depositing a first conductive layer in said first trench to cover the surface of said third silicon layer, said first silicon oxide layer, said second silicon layer, and said first dielectric layer;
removing partial said first conductive layer to expose said third silicon layer and a partial region of said first dielectric layer, wherein the remaining part of said first conductive layer is used as a first electrode of said trench capacitor;
depositing a second dielectric layer in said first trench to cover said partial region of said first dielectric layer and said remaining part of said first conductive layer;
depositing a second conductive layer in said first trench to cover said second dielectric layer;
removing partial said second conductive layer and partial said second dielectric layer to form a second trench, wherein the remaining part of said second conductive layer is used as a second electrode of said trench capacitor, and the remaining part of said second dielectric layer is used as a interlayer dielectric (ILD) in said trench capacitor;
depositing a third dielectric layer in said second trench to cover the surface of said second dielectric layer, said second conductive layer, and said third silicon layer;
removing partial said third dielectric layer to expose partial said second conductive layer and partial said third silicon layer;
depositing a polysilicon layer to fill up said second trench, wherein said polysilicon layer is used as a contact plug and is electronically connected to said second electrode of said trench capacitor;
forming a gate of a MOS transistor on said third silicon layer;
forming a first ion doped region of said MOS transistor in said third silicon layer;
forming a second ion doped region of said MOS transistor in said polysilicon layer, wherein said second ion doped region is electrically connected to said second electrode of said trench capacitor through said polysilicon layer;
removing partial said third silicon layer, partial first silicon oxide layer, and partial said second silicon layer to form a third trench;
depositing a fourth dielectric layer in said third trench to cover the surface of said third silicon layer, said first silicon oxide layer, and said second silicon layer;
removing partial said fourth dielectric layer to expose partial said second silicon layer; and
depositing a third conductive layer to fill up said third trench, wherein said third conductive layer is electrically connected to said first electrode of said trench capacitor through said second silicon layer.

6. The method according to claim 5, wherein said first dielectric layer, said second dielectric layer, said third dielectric layer, and said fourth dielectric layer are silicon oxide layers.

7. The method according to claim 5, wherein said second dielectric layer is an oxide-nitride-oxide layer.

8. The method according to claim 5, wherein said first conductive layer, said second conductive layer, and said third conductive layer are polysilicon layers.

9. A method for manufacturing a trench DRAM, said method comprising the steps of:
providing a structure, said structure comprises a first dielectric layer and a first silicon layer on said first dielectric layer;
removing partial said first silicon layer and partial said first dielectric layer to form a first trench;
performing a first oxygen-ion implantation on said first silicon layer to form a first silicon oxide layer, wherein said first silicon oxide layer divides said first silicon layer into two parts: one is a second silicon layer beneath said first silicon oxide layer, and the other is a third silicon layer over said first silicon oxide layer;
depositing a first conductive layer in said first trench to cover the surface of said third silicon layer, said first silicon oxide layer, said second silicon layer, and said first dielectric layer;
removing partial said first conductive layer to expose said third silicon layer and a partial region of said first dielectric layer, wherein the remaining part of said first conductive layer is used as a first electrode of said trench capacitor;
depositing a second dielectric layer in said first trench to cover said partial region of said first dielectric layer and said remaining part of said first conductive layer;
depositing a second conductive layer in said first trench to cover said second dielectric layer;
removing partial said second conductive layer and partial said second dielectric layer to form a second trench, wherein the remaining part of said second conductive layer is used as a second electrode of said trench capacitor, and the remaining part of said second dielectric layer is used as a interlayer dielectric (ILD) in said trench capacitor;
depositing a third dielectric layer in said second trench to cover the surface of said second dielectric layer, said second conductive layer, and said third silicon layer;
removing partial said third dielectric layer to expose partial said second conductive layer and partial said third silicon layer;
depositing a polysilicon layer to fill up said second trench, wherein said polysilicon layer is used as a contact plug and is electronically connected to said second electrode of said trench capacitor;
performing a second oxygen-ion implantation on said third silicon layer to form a second silicon oxide layer, wherein said second silicon oxide layer divides said third silicon layer into two parts: one is a fourth silicon layer beneath said second silicon oxide layer, and the other is a fifth silicon layer over said second silicon oxide layer;
forming a gate of a MOS transistor on said third silicon layer;
forming a first ion doped region of said MOS transistor in said fifth silicon layer;
forming a second ion doped region of said MOS transistor in said polysilicon layer, wherein said second ion doped region is electrically connected to said second electrode of said trench capacitor through said polysilicon layer;
removing partial said fifth silicon layer, partial said second silicon oxide layer, partial said fourth silicon layer, partial said first silicon oxide layer, and partial said second silicon layer to form a third trench;
depositing a fourth dielectric layer in said third trench to cover the surface of said fifth silicon layer, said second silicon oxide layer, said fourth silicon layer, said first silicon oxide layer, and said second silicon layer;
removing partial said fourth dielectric layer to expose partial said second silicon layer;
depositing a third conductive layer to fill up said third trench, wherein said third conductive layer is electrically connected to said first electrode of said trench capacitor through said second silicon layer;
removing partial said fifth silicon layer, partial said second silicon oxide layer, and partial said fourth silicon layer to form a fourth trench;
depositing a fifth dielectric layer in said fourth trench to cover the surface of said fifth silicon layer, said second silicon oxide layer, and said fourth silicon layer;
removing partial said fifth dielectric layer to expose partial said fourth silicon layer;
depositing fourth conductive layer to fill up said fourth trench.

10. The method according to claim 9, wherein said first dielectric layer, said second dielectric layer, said third dielectric layer, said fourth dielectric layer and said fifth dielectric layer are silicon oxide layers.

11. The method according to claim 9, wherein said second dielectric layer is an oxide-nitride-oxide layer.

12. The method according to claim 9, wherein said first conductive layer, said second conductive layer, and said third conductive layer are polysilicon layers.
